(19) United States
(12) Patent Application Publication
(10) Pub. No.: US 2004/0238210 A1
(43) Pub. Date: Dec. 2, 2004

(54) Electronic module with protective bump

(76) Inventor: Francois Droz, La Chaux-de-Fonds (CH)

Correspondence Address: Cliffor W Browning, Woodard Emhardt, Bank One Center/Tower, 111 Monument Circle Suite 3700, Indianapolis, IN, 46204-5137, US

(21) Appl. No.: 10/489,880

(22) PCT Filed: Oct. 8, 2002
(86) PCT No.: PCT/IB02/04156

(30) Foreign Application Priority Data
Oct. 9, 2001 (CH) 1861/01

(51) Int. Cl. H05K 1/03; H05K 3/30

(52) U.S. Cl. 174/258; 174/260; 29/841

(57) ABSTRACT

The aim of this invention is to obtain a very cheap electronic module while maintaining a high level of reliability regardless of the field of application. In particular, this concerns the protection of an electronic circuit that is integrated into the module by means of insulating layers.

The electronic module according to the invention comprises an assembly including a substrate, a conductive layer including a plurality of tracks and at least one electronic component. This assembly constituting an electronic circuit (1) is provided with a first area free of component (A) and a second area (B) where the electronic component (3) is located. This circuit (1) is covered on at least one of its faces with an insulating layer (2) with a generally uniform thickness. The electronic module is characterized in that this insulating layer (2) fits the first area (A) and includes in the second area (B) at least one bump (4) obtained by pressing the insulating layer (2) with a plate (20) including a depression (4′).

The object of this invention also concerns a manufacturing method of an electronic module characterized in that the assembly of the insulating layer (2) on the circuit face including the electronic component (3) is achieved by lamination by means of a plate (20) including at least one depression (4′) in front of the area (B) where the electronic component (3) is located on the circuit (1).

This invention concerns an electronic module comprising several superimposed layers and at least one electronic component, as well as a manufacturing process for this type of module.

The invention concerns modules manufactured by assembling several layers, namely a substrate, a conductive layer and at least one protection layer. This type of electronic module includes cards, smart cards, tickets or tokens. They comprise at least one support that is usually flexible, an antenna and an electronic component that is, in most cases, a chip. The electronic module, according to the invention, is present in many applications as identification means for persons or objects, as access control or for payment.

The object of this invention particularly focuses on modules comprising an insulating support, called a substrate, that is usually flexible and thin and on which a plurality of conductive tracks and/or a coil used as an antenna is applied. An electronic component is connected to the circuit formed by the tracks of the conductive layer. The type of assembly comprising a substrate, conductive layer and electronic component constitutes an electronic circuit. The latter has an insulating layer covering at least one face. This layer is used to protect the circuit against mechanical and chemical attacks (corrosion).

Some modules are known to those skilled in the art, that include electronic circuits that are protected by means such as:

coating in a resin according to different over molding techniques such as dip coating, projection or vacuum deposition of resin, this type of process is described in documents U.S. Pat. No. 6,215,401 and FR2769108.

application of flexible and elastic insulating layers that adapt to the module surface and that of components by means of platen rollers as described in document U.S. Pat. No. 6,114,962

covering with a shell molded in a sheet of synthetic material.

insertion into cavities of a support as in document JP02301155 where an adhesive sheet is molded onto a face of a module that will be bonded inside a cavity in the substrate of a card in such a way that the face free of glue flushes with the card surface. The module is thus protected by the card substrate that forms a gangue.

Protection means described above assure a uniform protection on the entire circuit surface; namely, the sensitive area including components and critical connections is protected in the same way as an empty area.

The arrangement of these protection means requires particularly delicate and expensive operations since the circuit to be protected is fragile. In fact, as the electronic components become increasingly complex, they support with difficulty the stresses to which they are subjected during module assembly by means of the lamination of various layers. These stresses are essentially mechanical (high pressure) and thermal (high temperatures). Furthermore, the manufacture of very substantial quantities of modules imposes the lowest possible costs and very fast execution.

The aim of this invention is to obtain a very cheap electronic module that maintains a high level of reliability regardless of the field of application. In particular this concerns the protection of the electronic circuit integrated into the module by means of insulating layers.

The aim of the present invention is also to propose a production method for an electronic module with this type of protection.

This aim is achieved with an electronic module comprising an assembly made up of a substrate, a conductive layer that includes a plurality of tracks and at least one electronic component, said assembly constituting an electronic circuit is provided with a first area free of component and a second area where the electronic component is located, said circuit having at least one of its faces covered with an insulating layer, characterized in that said insulating layer fits the first area and includes in the second area a deformation called bump, enclosing the electronic component, formed by the localized expansion of the insulating layer during the hot laminating of said layer with a plate including a depression or a hole.

The module according to the invention includes a relief over at least one of its faces, generally located above the electronic component. This relief or bump assures greater protection for the component in comparison to that which is offered to empty areas or areas that only include conductive tracks. Electronic components are usually mounted on the electronic circuit surface and concentrated in an area defined by the creation of a local excessive thickness on the circuit. Some applications require a module whose thickness must be reduced at least on the larger part of its surface in order to keep flexibility as high as possible. The module is distinguished by two well defined areas: a first thin and extended area that corresponds to an electronic circuit region without an electronic component and a thicker and smaller second area that forms a bump located in an area where one or more components are located.

A module can comprise a marking engraved in the protection layer or a hollow area reserved for a subsequent marking by printing or by supplying a small plate. Hollow parts can also be located on the component bump as well as on the surface surrounding the latter.

For example, electronic labels for baggage have a large flexible surface allowing inscriptions. They include an electronic circuit comprising an antenna and a chip that is located near the edge of the label. Each circuit face is covered with a thin insulating protection layer. The chip mounted superficially on the circuit forms an excessive thickness. The protection layer that also covers the chip forms a relief that encloses the outlines of the chip on one of the faces of the label. This relief or bump does not disrupt the use of the label that is attached to the baggage, preferably on the side near the relief. In fact, the label serves to identify an item of baggage by means of radio frequency (antenna and chip) and/or by visual means (marking of the surface).

The protection layer is generally made of a plastic film with a constant thickness on its entire surface. This layer forms the bump that encloses the component without touching it. The free space under the bump, around the component is either filled with air or glue, confined during the lamination of the protection layer.

In a module embodiment according to the invention, the component is surrounded by an over molding or a capsule before the lamination of the protection layer.

These different forms of filling the space between the component and the protection layer offer particular protection to the component, while the other parts of the module surface are directly covered with the protection layer without any intermediate space.

The object of this invention also concerns a method for manufacturing an electronic module comprising an assembly made up of a substrate, a conductive layer including a plurality of tracks and at least one electronic component, said assembly forming an electronic circuit is provided with a first area free of component and a second area where the electronic component is located, said circuit has at least one of its faces covered with an insulating layer, characterized in that the assembly of the insulating layer, on the circuit face including the electronic component is achieved using lamination by means of a plate including at least one depression positioned in front of the second area where the electronic component is located on the circuit.

The advantage of the above-described module manufacturing method is that it does not damage the electronic component during lamination. In fact, the depression machined in the laminating plate located in front of the component has a sufficient depth in order to prevent the pressing of the plate on the component. This depression can form a hollow with a closed bottom, or a hole whose depth is defined by the thickness of the laminating plate. During lamination, under the effect of heat and pressure, the viscosity of the material forming the protection layer is high. This material softened in this way penetrates into the depression of the plate to form the relief above the component. The outline of this relief takes then the same shape as that in the plate depression. The remaining part of the protection layer is laminated by direct pressure on the circuit areas without component.

The protection layer can be directly hot laminated onto the circuit. The material partially melts in order to adhere onto the circuit surface. The lamination plate depression forms the bump over the electronic component. This bump is filled with the air confined during lamination.

During lamination, it is also possible to use thermo-fusible glue or resin by application of an adhesive layer on the circuit surface. In this case, the glue, when melting, fills the relief that encloses the electronic component. This filling further improves the protection of the component.

According to a variant of the method, the protection layer can be pre-formed before lamination on an electronic circuit. In this case, a film of insulating material is formed, preferably by hot pressing, with a plate including at least one depression. Each depression of the plate forms a relief on the insulating material film. A subsequent step consists in superimposing this pre-formed protection layer on the circuit by adjusting the bumps with the component locations on the circuit. Lamination is then carried out with or without an adhesive layer, as described above.

According to another variant of the invention, a logo or other marking can be engraved into the lamination plate depression. The bump obtained on the protection layer will be provided with a relief marking corresponding to that which is engraved on the plate.

In general, every cavity, regardless of its shape, cut into the lamination plate creates a corresponding relief on the module protection layer.

Reciprocally, every relief on the lamination plate creates hollows in the protection layer. This case is used for example to produce a hollow on the bump intended to receive a marking plate. Thus the lamination plates include a hollow on the bottom of which is located a relief corresponding to the shape of the small plate to be inserted on the bump.

A frequent execution of electronic labels attached to a support consists in engraving a groove in the protection layer around the bump that encloses the electronic component or the chip. The laminating plate includes in this case a hollow for the bump and a relief around the latter for the groove. This groove forms a pre-cutting of the chip. The pulling up of this type of label from its support causes the tearing of the circuit along the pre-cutting and renders this label unusable.

The invention will be better understood thanks to the following detailed description that refers to the enclosed drawings given as a non-limitative example, in which:

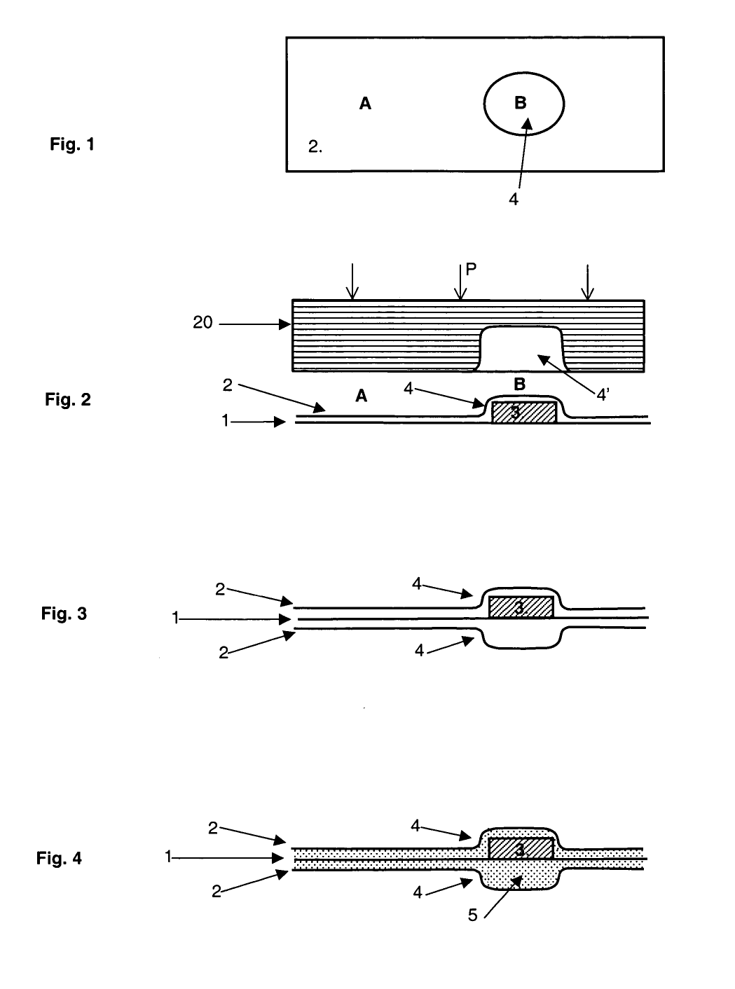

FIG. 1 represents an overview of an electronic module with bump

FIG. 2 represents a cross-section of an electronic module with a protection layer comprising a bump on one face.

FIG. 3 represents a cross-section of an electronic module with a protection layer comprising a bump on each face.

FIG. 4 represents a cross-section of an electronic module with a protection layer comprising a bump on each face and an adhesive layer

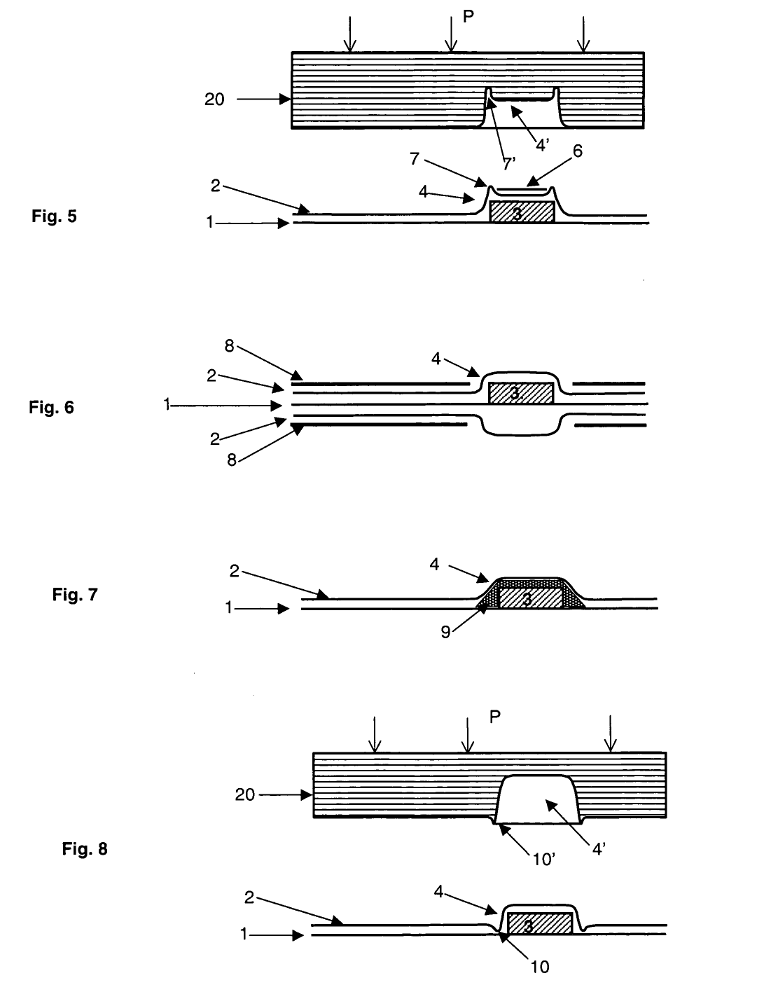

FIG. 5 represents a cross-section of an electronic module with a protection layer comprising a bump provided with a hollow

FIG. 6 represents a cross-section of an electronic module with a protection layer including a bump and an additional coating.

FIG. 7 represents a cross-section of an electronic module with a protection layer comprising a bump on an encapsulated component.

FIG. 8 represents a cross-section of an electronic module with a protection layer comprising a bump with pre-cutting

FIG. 1 shows a view from the upper face of an electronic module that includes two areas (A) and (B). The area (A), without an electronic component is usually thin, this thickness corresponding approximately to the thickness of the substrate of the electronic circuit (1) added to that of the insulating layer (2). The area (B) forms a bump (4) covering an electronic component.

FIG. 2 shows a cross-section of a module from FIG. 1 comprising an electronic circuit (1) on which an electronic component (3) and a protection layer (2) are assembled. The area (B) where the electronic component (3) is located forms a bump (4) on the circuit (1) enclosing the component (3). The space between the component (3) and the protection layer (2) is filled with air confined during the lamination of the protection layer (2) on the circuit (1).

The lamination plate (20) includes a depression (4′), the outline of which corresponds to that of the bump (4). After superimposing the protection layer (2) over the circuit (1), lamination is carried out by hot pressing (P) the plate on the assembly comprising the circuit and protection layer. The plate is arranged in such a way that the depression (4′) is located above the component (3), the protection layer material (2) penetrates into the depression (4′) by heat effect and creates a bubble that forms the bump (4). In most cases, bump height (4) is lower than the depression depth (4′) of the plate (20). In fact, the latter plays a different role to that of a mould creating a shape similar to the volume of a cavity. At this point, the expansion of the air surrounding the component contributes to the formation of the bump (4) whose external surface is not necessarily in contact with the inner surface of the depression (4′) of the plate (20).

Tests have shown that the depression (4′) can be replaced by a hole traversing the pressing plate (20). The bump (4) formed in this way will have an outline corresponding to that of the hole and a height limited by the component (3) and the confined air enclosing the component (3).

FIG. 3 shows a similar module to that in FIG. 2 with a second protection layer (2) laminated on the second electronic circuit face (1). This layer also includes a bump (4), which protects the component (3) underneath.

FIG. 4 represents the module in FIG. 3 where the protection layers (2) are laminated on each face by means of an adhesive layer (5) previously applied over the circuit. Glue, which is usually thermo-fusible, fills the space between the electronic component (3) and the bump (4). The protection of the component (3) is therefore better than that which is proposed in FIG. 2 where the space is filled with air.

FIG. 5 shows an example of an execution of a relief (7) on the bump (4) that constitutes the edges of a hollow in which a small plate (6) can be bonded. In this case the laminating plate (20) includes a cavity (4′), on the bottom of which a groove (7′) delineates the outline of the hollow on the bump (4) where the small plate (6) will be housed. In this case the depth and shape of the cavity (4′) is adapted to that of the bump (4) that is to be created on the module protection layer (2).

FIG. 6 shows the module in FIG. 2 provided with a supplementary protection layer (8) around the bump (4). This layer is for example a personalization coating (8) that allows the printing of the module owner's own data.

FIG. 7 shows a supplementary protection for the component (3) made up of an over molding or a capsule (9), which is applied on the component before the lamination of the protection layer (2).

FIG. 8 shows the pre-cutting (10) of an electronic component made up of a groove (10) that surrounds all or part of the bump (4). The laminating plate (20) includes in this case a relief (10′) that surrounds the edge of the cavity (4′) that serves to form the bump (4). The thickness of the module at the level of the bottom of the groove (10) is close to that of the electronic circuit (1). This extremely fragile area is permitted in certain applications when the destruction of the module is required, for example during pulling up from its support.

1-14. (canceled).

15. Electronic module comprising an assembly made up of a substrate, a conductive layer that includes a plurality of tracks and at least one electronic component (3), said assembly constituting an electronic circuit (1) is provided with a first area free of component (A) and a second area (B) where the electronic component (3) is located, said circuit (1) having at least one of its faces covered with an insulating layer (2), characterized in that said insulating layer (2) fits the first area (A) and includes in the second area (B) a deformation called bump (4), enclosing the electronic component (3), formed by the localized expansion of the insulating layer (2) during the hot laminating of said layer with a plate (20) including a depression (4′) or a hole.

16. Electronic module according to claim 15, characterized in that the space between the electronic component (3) and the insulating layer (2) covering the bump (4) is filled with air.

17. Electronic module according to claim 15, comprising an adhesive layer (5) between the electronic circuit (1) and the insulating layer (2), characterized in that the adhesive layer (5) mainly fills the space between the electronic component (3) and the insulating layer (2) of the bump (4).

18. Electronic module according to claim 15, characterized in that the electronic component (3) located under the bump (4) is protected by a capsule (9).

19. Electronic module according to claim 15, characterized in that the bump (4) includes an area formed in a hollow in order to receive a marking (7) and/or an engraving (10).

20. Method for manufacturing an electronic module comprising an assembly made up of a substrate, a conductive layer including a plurality of tracks and at least one electronic component (3), said assembly forming an electronic circuit (1) is provided with a first area (A) free of component and a second area (B) where the electronic component (3) is located, said circuit (1) has at least one of its faces covered with an insulating layer (2) characterized in that the assembly of the insulating layer (2), on the circuit face including the electronic component (3) is achieved using lamination by means of a plate (20) including at least one depression (4′) positioned in front of the second area (B) where the electronic component (3) is located on the circuit (1).

21. Method according to claim 20, characterized in that lamination causes a deformation (4) of the insulating layer (2) around the component (3) under the effect of the pressure and heat applied during lamination, said deformation creates a bump (4) having the same outline as the depression (4′) in the laminating plate (20).

22. Method according to claim 21, characterized in that one and/or the other face of the electronic circuit (1) is covered with an adhesive layer (5) before the lamination of the insulating layer (2), said adhesive layer (5) penetrating, during lamination, into the space defined between the electronic component (3) and the bump (4) of the insulating layer (2).

23. Method according to claim 20, characterized in that lamination is carried out by means of a plate (20) including at least one relief, said relief deforms the insulating layer (2) by creating a hollow (7, 10) with a shape similar to the relief on the laminating plate.

24. Method according to claim 20, characterized in that an over molding or a capsule (9) serving as supplementary protection is applied on the component (3) before the lamination of the insulating layer (2).

25. Method according to claim 20, characterized in that at least one bump (4) is carried out on the insulating layer (2) in a first step and the assembly of said pre-formed insulating layer (2) on the electronic circuit (1) is carried out in a second step by superimposing the bump (4) of the insulating layer (2) on the electronic component (3) of the circuit (1).

26. Method according to claim 20, characterized in that the lamination is carried out by means of a plate (20) including a cavity (4′) at the bottom of which a groove (7′) delineates the outline of said cavity and forms a corresponding relief (7) on the bump (4) obtained.

27. Method according to claim 20 characterized in that the depression (4′) of the plate (20) for lamination is replaced by a hole traversing said plate (20).

28. Method according to claim 20, characterized in that a supplementary protection layer (8) is assembled around the bump (4), said layer serving as a personalization coating allowing the printing of the module owner's own data.
